(19) United States
(12) Patent Application Publication
(10) Pub. No.: US 2026/0254261 A1
(43) Pub. Date: Aug. 27, 2026

(54) SCALABLE BATTERYLESS POWER SUPPLY OR SBPS

(71) Applicant: NATIONAL RESEARCH COUNCIL OF CANADA, Ottawa (CA)

(72) Inventors: Chundra Ramful, Ottawa (CA); Salima Alem, Ottawa (CA)

(21) Appl. No.: 19/160,975

(22) PCT Filed: Feb. 29, 2024
(86) PCT No.: PCT/IB2024/051961

§ 371 Date: Aug. 29, 2025

Related U.S. Application Data
(60) Provisional application No. 63/487,904, filed on Mar. 2, 2023.

(51) Int. Cl. H02J 7/35; H02J 7/34; H02J 7/90; H10K 39/12

(52) U.S. Cl. CPC H02J 7/35; H02J 7/345; H02J 7/933; H10K 39/12; H02J 2207/20; H02J 2207/50

(57) ABSTRACT

A scalable batteryless power supply is provided for harvesting light energy and powering a load, comprising a light energy harvester; a circuit for periodically sampling an output voltage of the energy harvester and in response generating a reference voltage; and a plurality of cascaded energy storage branches for storing energy from the energy harvester and powering the load, wherein each energy storage branch triggers charging of a downstream energy storage branch provided the voltage thereacross remains above the reference voltage.

### FIELD OF THE INVENTION

The present disclosure relates generally to power supplies, and more particularly to a scalable batteryless power supply and method of operating same.

### BACKGROUND OF THE DISCLOSURE

Energy harvesting has become increasingly popular with the emergence and exponential proliferation of “Internet of Things” (IoT) devices where power consumption typically ranges from hundreds of microwatts to hundreds of milliwatts. A fundamental challenge of autonomously powered systems is to harness energy from intermittent sources in order to operate electronic components in a predictable and reliable manner.

Proper storage and management of harvested energy is key to success in this context. Most prior art systems are based either solely on rechargeable batteries and/or on a combination of rechargeable batteries and supercapacitors. In spite of their widespread use, rechargeable batteries present disadvantages, such as requiring dedicated circuitry for charging/discharging as well as for ensuring safety and reliability, a limited number of charge/discharge cycles (typically less than a few thousands), labour costs for battery replacement and environmental complications arising from recycling. Rechargeable batteries have disadvantages in terms of their safety and environmental impact.

It is also known in the art to use supercapacitors, which are well suited as storage devices in IoT platforms relying on energy harvesting, as long as operating conditions are within the specified values. For example, supercapacitors can handle random variations of the input voltage and, unlike batteries, the number of charge/discharge cycles that they can undergo without degrading, is in the order of many hundreds of thousands of cycles. Furthermore, they are not prone to bursting into flames due to ageing, misuse or faulty charging devices, and are a suitable alternative for many niche applications.

Nonetheless, supercapacitors are not ideal components and therefore require circuitry to manage the non-ideal characteristics of supercapacitors, as well as mitigate the inherent unpredictability associated with energy harvesting such as minimal start-up time with no prior stored energy or depleted energy, pre-conditioning/pre-charging before use, and an ability to fully absorb/cushion short term to long term energy harvesting gaps.

Ideally, the start-up time should be as small as possible (e.g. in the order of a couple of minutes at most) and pre-conditioning/pre-charging should not be required before deployment. The ability to fully bridge energy harvesting gaps lasting up to a few hours is required to address short term unpredictability inherent to energy harvesting systems. It is also desirable for batteryless systems to guarantee reliable operation over a span of tens of hours and even days without any energy replenishment. Then, once favourable conditions return after prior stored energy has been depleted, such systems should be able to resume operation as fast as possible.

The unpredicability with energy harvesting is not only the occurrence of “dark” periods but also the possibility of having energy harvesting peaks. Prior art systems cater for “nominal” or average energy harvesting levels or conditions because of their limited storage capacity.

Basic batteryless systems usually incorporate one or more supercapacitors with a relatively small storage capacity so that they can start operating within a few minutes without any prior stored energy. Unfortunately, the maximum amount of energy that can be stored in such systems, is able to bridge only very short term energy harvesting gaps. This results in a lost opportunity should optimal energy harvesting conditions last for long periods.

Larger supercapacitors allow more energy to be stored but they require a longer time to reach the minimum voltage that is essential for electronic components to start operating, and hence require pre-charging. Some batteryless power systems contain a small device coupled with a larger device to cut down the pre-charge duration under certain conditions.

The following prior art is relevant to this description:
System for energy harvesting and/or generation, storage, and delivery U.S. Pat. No. 7,982,439 B2 (19 Jul. 2011);
Method and apparatus for harvesting energy US 8,362,745 B2 (29 Jan 2013);
Energy harvesting for IoT devices U.S. Pat. No. 10,153,650 B2 (11 Dec. 2018);
Sensor system with energy harvesting US 2017/0237466A1 (17 Aug. 2017);
Battery charger and method for collecting maximum power from energy harvester circuit U.S. Pat. No. 9,063,559 B2 (23 Jun. 2015);
Harvesting power from ambient energy in an electronic device U.S. Pat. No. 10,651,683 B2 (12 May 2020);
Harvesting power from multiple energy sources U.S. Pat. No. 9,197,143 B1 (24 Nov. 2015);
Energy harvesting U.S. Pat. No. 9,774,277 B2 (26 Sep. 2017);
Systems capable of self-harvesting energy from wireless devices and methods of using the same U.S. Pat. No. 9,985,461 B2 (29 May 2018);
Energy harvesting device KR 20100117432A (2009);
Method and apparatus for energy harvesting and/or generation, storage, and delivery
US 2010/0060231 A1 (11 Mar. 2010);
Capacitors with low equivalent series resistance US 7,864,507 B2 (4 Jan. 2011);
Battery protection circuit and method for energy harvester circuit U.S. Pat. No. 8,253,389 B2 (28 Aug. 2012);
Passive RF energy harvesting scheme for wireless sensor US 2012/0256492 A1 (11 Oct. 2012)
Self-sustaining energy harvesting system AU 2015362713 B2 (15 Dec. 2015);
Hybrid battery system for portable electronic devices EP 2590249 B1 (27 Mar. 2012);
New circuit topology for energy harvesting with pulsed power DE 112011101163T5 (2011);
Energy scavenging power supply US 2012/0292993 (22 Nov. 2012);
Energy harvesting sensor system and method therefor US 2019/0020290 A1 (17 Jan. 2019);
Energy converting apparatus and method U.S. Pat. No. 9,735,602 B2 (15 Aug. 2017);
Method and system for storing energy and providing a regulated output US 2019/0267678 A1 (29 Aug. 2019);
Micro-energy harvester for battery free applications U.S. Pat. No. 10,044,218 B2 (7 Aug. 2018);

Power management integrated circuit and energy harvesting system KR 1020190006507A (2019);
Method, system and device for power generation WO 2017/053946 A1 (2017);

Integrated circuit energy harvester U.S. Pat. No. 9,379,543 B2 (2016);
luXbeacon—A batteryless beacon for green IoT: design, modelling and field tests, by Kang Eun Jeon et al. (IEEE Internet of Things Journal, Vol. 6 No. 3, 3 Jun. 2019);
S6AE102A/S6AE103A Energy harvesting PMIC for wireless sensor node Infineon Technologies (formerly Cypress);
Energy-aware adaptive supercapacitor storage system for multi-harvesting solutions, by Albert Alvarez-Carulla et al. (IEEE Design of Circuits and Integrated Systems, 2018);
Powering batteryless embedded platforms by piezoelectric transducers: a pilot study, by Michal Prauzek et al. (Elektronika, ISSN 1392-1215, Vol. 25, No. 2, 2019);
Hybrid energy storage system for mobile RF energy harvesting wireless sensors, by Dr. Bilal Munir. (Ph. D Thesis, July 2020);
Review of power conversion and energy management for low-power, low-voltage energy harvesting powered wireless sensors, by David Newell & Maeve Duffy. (IEEE Transactions on Power Electronics, 10 Oct. 2019);
Energy harvesting sources, storage devices and system topologies for environmental wireless sensor networks: A review, by Michal Prauzek et al. (MDPI Sensors, 27 Jul. 2018);
Photovoltaic energy harvesting wireless sensor node for telemetry applications optimized for low illumination levels, by Ljubomir Vracar et al. (MDPI Electronics, 1 Jun. 2016);
UR-SolarCap: An open source intelligent auto-wakeup solar energy harvesting system for supercapacitor-based energy buffering, by Moeen Hassanalieragh et al. (IEEE Access, 7 Mar. 2017);
Size and topology optimisation for supercapacitor-based sub-Watt energy harvesters, by Sehwan Kim and Pai H. Chou. (IEEE Transactions on power electronics, April 2013);
Ambient energy harvester design for a wireless sensor network, by Ranjana Joshi and Jin Zhu. (IEEE, 2015);
Reconsidering batteries in energy harvesting sensing, by Neal Jackson, Josha Adkins and Prabal Dutta. (ACM ISBN 978-1-4503-6047-0, November 2018);
Energy harvesting in wireless sensor networks: A comprehensive review, by Faisal Karim Shaikh and Sherali Zeadally; (Elsevier, Renewable and Sustainable Energy Reviews, 2016);
Energy harvesting towards self-powered IoT devices, by Hassan Elahi et al. (MDPI Energies, 22 Oct. 2020);
Energy-aware system design for batteryless LPWAN devices in IoT applications, by Mehmet Erkan Yuksel and Huseyin Fidan. (MDPI Energies, 22 Oct. 2020);
Advanced monitoring systems based on batteryless asset tracking modules energized through RF wireless power transfer, by Roberto La Rosa et al. (MDPI Sensors, 26 May 2020);
Energy harvesting for battery-free wireless sensors network in a reinforced concrete beam, by Alassane Sidibe et al. (Proceedings of the 50th European Microwave Conference, January 2021);
Strategies and techniques for powering wireless sensor nodes through energy harvesting and wireless power transfer, Roberto La Rosa et al. (MDPI Sensors, 12 Jun. 2019);
A 65 nm energy harvesting ULP SoC with 256 KB Cortex-MO enabling an 89.1 uW continuous machine health monitoring wireless self-powered system, Jonathan K. Brown et al. (IEEE International Solid-State Circuits Conference, 2020);
Maximum power point tracking and photovoltaic energy harvesting for Internet of Things: A comprehensive review, Fahad Faraz Ahmad et al. (Elsevier, Sustainable Energy Technologies and Assessments, 18 Jun. 2021);
Survey of energy harvesting technologies for wireless networks, by Alexander J. Williams et al. (IEEE Access, 2 Jun. 2021);
Ember: Energy management of batteryless event detection sensors with deep reinforcement learning, by Francesco Fraternali et al. (ACM ISBN 978-1-4503-7590-0, November 2020);
On the impact of mobility on batteryless RF energy harvesting system performance, Bilal Munir and Vladimir Dyo. (MDPI Sensors, 23 Oct. 2018);
A comprehensive review of maximum power point tracking algorithms for photovoltaic systems, by Nur Atharah Kamarzaman & Chee Wei Tan. (Elsevier, Renewable and Sustainable Energy Reviews, 17 May 2014);
Energy replenishment using renewable and traditional energy resources for sustainable wireless sensor networks: A review, by Fayaz Akhtar et al. (Elsevier, Renewable and Sustainable Energy Reviews, 2015); 51. AN1007—Charging a supercapacitor from a solar cell energy harvester, by So-Yeon Leem. (CAP-XX, Rev 1.3, September 2020);
User manual for APPEB1011—Direct charging supercapacitor energy harvester evaluation board, by Henry Huang. (CAP-XX, Rev 1.2, May 2020);
Application report—bq25504 optimization of MPPT algorithm, by Umar Lyles and Yogesh Ramadass. (Texas Instruments, March 2012)

Any discussion of problems provided in this section has been included in this disclosure solely for the purposes of providing a background for the present invention, and should not be taken as an admission that any or all of the discussion was known at the time the invention was made.

### BRIEF DESCRIPTION OF THE DRAWING FIGURES

The subject matter of the present disclosure is particularly pointed out and distinctly claimed in the concluding portion of the specification. A more complete understanding of the present disclosure, however, may best be obtained by referring to the detailed description and claims when considered in connection with the drawing figures, wherein like numerals denote like elements and wherein:

FIG. 1 illustrates a scalable batteryless power supply, in accordance with an exemplary embodiment.

FIG. 2 illustrates details of a comparator circuit of the system illustrated in FIG. 1.

FIG. 3 illustrates a scalable batteryless power supply, in accordance with an alternative embodiment.

It will be appreciated that elements in the figures are illustrated for simplicity and clarity and have not necessarily been drawn to scale. For example, the dimensions of some of the elements in the figures may be exaggerated relative to other elements to help to improve understanding of illustrated embodiments of the present disclosure.

### DETAILED DESCRIPTION OF EXEMPLARY EMBODIMENTS

The description of exemplary embodiments of the present disclosure provided below is merely exemplary and is intended for purposes of illustration only; the following description is not intended to limit the scope of the invention disclosed herein. Moreover, recitation of multiple embodiments having stated features is not intended to exclude other embodiments having additional features or other embodiments incorporating different combinations of the stated features.

As set forth in more detail below, exemplary embodiments of the disclosure relate to a scalable batteryless power supply having multiple supercapacitors arranged in a cascade topology to provide a simple, yet effective method to solve the typical challenges arising in a batteryless system. In essence, each supercapacitor triggers the charging of a downstream supercapacitor provided its voltage remains slightly above a reference voltage.

The scalable batteryless power supply set forth herein also allows excess harvested energy to be stored instead of being wasted, as in prior art approaches.

In an aspect of this description, there is provided a scalable batteryless power supply for connection between an energy harvester and a load, comprising: a maximum power point tracking circuit and input switch for periodically sampling an output voltage of the energy harvester and in response generating a threshold voltage; a plurality of cascaded energy storage branches separated by additional switches, for cascaded storage of energy from the energy harvester and for powering the load; and wherein successive ones of the cascaded energy storage branches are activated by the additional switches in sequence from a lowest capacitance to successively higher capacitances based on the threshold voltage.

According to another aspect, there is provided a scalable batteryless power supply for harvesting light energy and powering a load, comprising: a light energy harvester; a circuit for periodically sampling an output voltage of the energy harvester and in response generating a reference voltage; and a plurality of cascaded energy storage branches for storing energy from the energy harvester and powering the load, wherein each energy storage branch triggers charging of a downstream energy storage branch provided the voltage thereacross remains above the reference voltage.

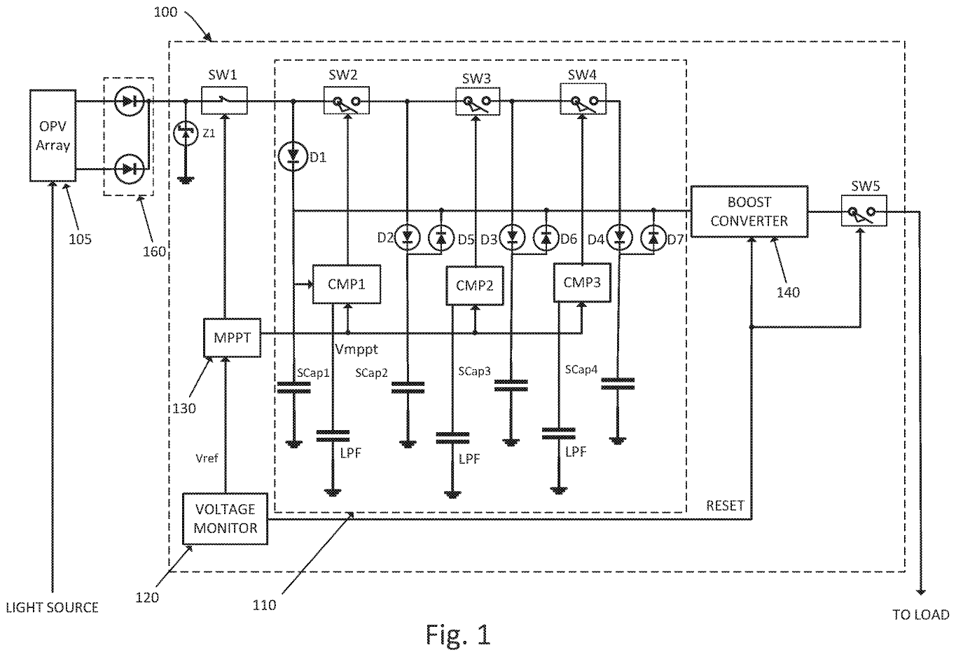

FIG. 1 illustrates a scalable batteryless power supply 100 for storing energy harvested by an energy harvester, such as an organic photovoltaic (OPV) array 105 of solar cells, from a light source and powering a load, such as an IoT device. OPV array 105 can comprise multiple printed organic solar cells connected in series and in parallel. ORing Schottky diodes 160 fulfil the dual task of isolating any malfunctioning parallel OPV branch(es) as well as preventing power supply 100 from back driving the OPV array.

The power supply 100 includes a plurality of cascaded energy storage branches or channels 110, voltage monitor 120, maximum power point tracking (MPPT) circuit 130, boost converter 140, and an input switch SW1 and an output switch SW5. The power supply 100 is characterized by features such as: fast power-up from a cold start, no requirement for pre-conditioning/pre-charging before use, and no requirement for any control algorithm to manage reference voltages, energy storage or load management. The scalable batteryless power supply 100 works with organic photovoltaic devices or any other energy harvesting source 105. The use of cascaded energy storage branches or channels 110 serves to increase energy storage capacity and also ensures that the energy harvesting mechanism is operating at an optimum voltage to maximize power transfer. By implementing cascaded energy storage, the scalable batteryless power supply 100 provides resilience without compromising fast power-up either from a cold start or from total energy depletion following a prolonged period during which energy cannot be replenished.

The cascaded energy storage branches 110 are separated by switches SW2, SW3, SW4 (e.g. P-channel MOSFET switches) and include supercapacitors (SCap1, SCap2, SCap3, SCap4), comparators (CMP1, CMP2, CMP3), Schottky diodes (D1, D2, D3, D4, D5, D7), and low pass filter capacitors LPF. A Zener diode Z1 can also be used between Oring diodes 160 and Sw1 to clip Voc in the event of spurious voltage spikes from OPV array 105 resulting from unexpectedly bright light.

In the embodiment of FIG. 1, the smallest supercapacitor SCap1, whose value is in the order of 10 mF to 47 mF (preferably approximately 22 mF), has a “highest priority” in terms of storing energy, in that it is kept fully charged and dictates the power-up duration from a cold start. A 22 mF capacitance is desirable because it shortens to power-up duration from a cold start. However, if a 22 mF capacitance cannot sustain the inrush current of the boost converter 140, a 47 mF supercapacitor may be used resulting in a longer time to power-up.

Excess energy is stored in a cascaded sequence, i.e. in Scap2 next, then in SCap3 and finally in SCap4. If optimum conditions for harvesting energy last sufficiently long and if the power consumption rate is low enough, all four supercapacitors SCap1, Scap2, SCap3 and SCap4 eventually become fully charged, all while the load (e.g. IoT device) remains operational.

Although FIG. 1 shows four energy storage branches 110, a fewer or greater number of energy storage branches is possible (e.g. 7, 12 or even 20 branches).

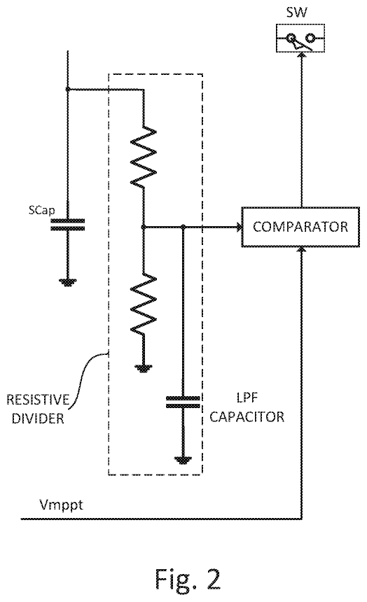

Details of each comparator (CMP1, CMP2, CMP3) are shown in FIG. 2. Each comparator has two inputs. One input senses the voltage across the supercapacitor (Scap) via a high impedance resistive divider, while the other input is connected to the Vmppt signal generated by the maximum power point tracking (MPPT) subsystem, discussed below. The low pass filter (LPF) capacitor, which is typically in the order of 1 μF to 4.7 μF, for preventing the comparator from excessively toggling due to rapid fluctuations of the voltage (Vscap) across the supercapacitor (Scap).

In order to efficiently transfer maximum power from the OPV array 105 to the load, impedances must match. Because OPV array 105 is subjected to different intensities of light, the impedance changes. MPPT circuit 130 tracks the impedance of the OPV source and makes dynamic adjustments in order to maximize the transfer of power from OPV array 105 to the cascaded energy storage branches 110. MPPT circuit 130 samples the output voltage (Voc) of OPV array 105 to periodically determine impedance (e.g. every 30 seconds) by opening SW1 and measuring Voc, as discussed below.

Maximum power transfer happens at a ratio of Voc that barely changes with illumination intensity. Thus, the scalable batteryless power supply 100 set forth herein employs a very simple MPPT strategy based on the buffered high impedance resistive divider, where Vmppt=Voc×Ratio, and where Ratio changes minimally with illumination intensity.

In operation, once the OPV array 105 starts harvesting light, current flows into SCap1 causing its voltage, Vscap1, to rise. The higher the light intensity, the faster voltage builds across SCap1. In the event that the scalable batteryless power supply 100 is powering up from a “cold start” under low lighting conditions, it is preferable to isolate the rest of the circuitry from supercapacitor Scap1 so that Scap1 can charge up as fast as possible. To that end, voltage monitor 120, which in embodiments can be a voltage monitor which has an internal voltage reference, to provide the required isolation. In some embodiments, two separate voltage monitors may be provided with different thresholds more operational flexibility, where one is responsible for power-up while the other monitor engages/isolates the load when sufficient energy has been accumulated. Provided Vscap1 remains below the reference voltage Vref, voltage monitor 120 keeps the MPPT circuit 130 as well as the boost converter 140 disabled and all of the harvested energy goes into SCap1. When Vscap1 increases beyond Vref, the voltage monitor 120 enables boost converter 140 and MPPT circuit 130, while output switch SW5 stays OFF to prevent inrush current. The open-circuit voltage (Voc) of OPV array 105 is then sampled, as discussed above, by turning OFF switch SW1 and held in MPPT circuit 130 until the next voltage sampling.

SW5 is turned ON a few seconds after the boost converter 140 has been enabled and at this stage, the load (e.g. IoT device) starts operating. Harvested current keeps flowing into SCap1 except for the moments when SW1 is forced open under the action of the MPPT circuit 130 in order to sample Voc.

If energy harvesting lasts long enough, Vscap1 eventually exceeds a threshold voltage, Vmppt, at which point, comparator CMP1 toggles and turns on SW2, which starts SCap2 charging.

Diode D1 ensures that SCap1 does not lose its charge to SCap2 when SW2 is on. This ensures Vscap1 does not fall below the specified input voltage range of boost converter 140. The boost converter 140 continues drawing current from SCap1, whose charge is no longer being replenished, such that the voltage Vscap1 across Scap1 starts decreasing.

Comparator CMP1 toggles when Vscap1 falls below Vmppt, SW2 is turned off and SCap2 stops charging while SCap1 recovers its lost charge via D1. Voltage Vscap1 eventually builds up and CMP1 toggles, causing SW2 to turn ON and resume the charging of SCap2.

The on/off toggling of CMP1 ensures that the average voltage of SCap1 stays close to Vmppt.

If energy harvesting lasts long enough, SCap2 is eventually able to charge slightly above Vmmpt, whereupon comparator CMP2 toggles and turns on SW3 to charge SCap3. Diode D2 prevents SCap2 from being discharged by SCap3. The charging current for the latter comes from the OPV array 150 as long as SW1 and SW2 are closed.

Since SCap1 is constantly supplying current to the boost converter 140 and current from OPV array 150 is being diverted into SCap3, voltage Vscap1 eventually falls below Vmppt. When comparator CMP1 toggles and SW2 is turned off, the charging of SCap3 is temporarily halted.

Vscap1 charges until Vscap1 exceeds threshold voltage Vmppt, whereupon SW2 turns on and allows current from the OPV array 105 to be accessible to the downstream SCaps. In the meantime, if Vscap2 remains above Vmmpt, SW3 is on and SCap3 resumes charging.

The repeated cycling of SW2 and SW3 under the action of CMP1 and CMP2 ensures that Vscap1 and Vscap2 fluctuate close to Vmppt and excess current keeps charging Scap3 in short bursts.

When SCap3 charges to the point that Vscap3 exceeds threshold voltage Vmppt, the above steps are repeated in the last of the cascaded energy storage branches 110 comprising CMP3, SW4 and SCap4.

With good lighting conditions and sufficient time, OPV array 105 is able to charge all four supercapacitors to the Vmppt voltage level. Any additional harvested energy causes Vscap1, Vscap2, Vscap3 and Vscap4 to slowly drift towards Voc at which point MPPT 130 ceases operating.

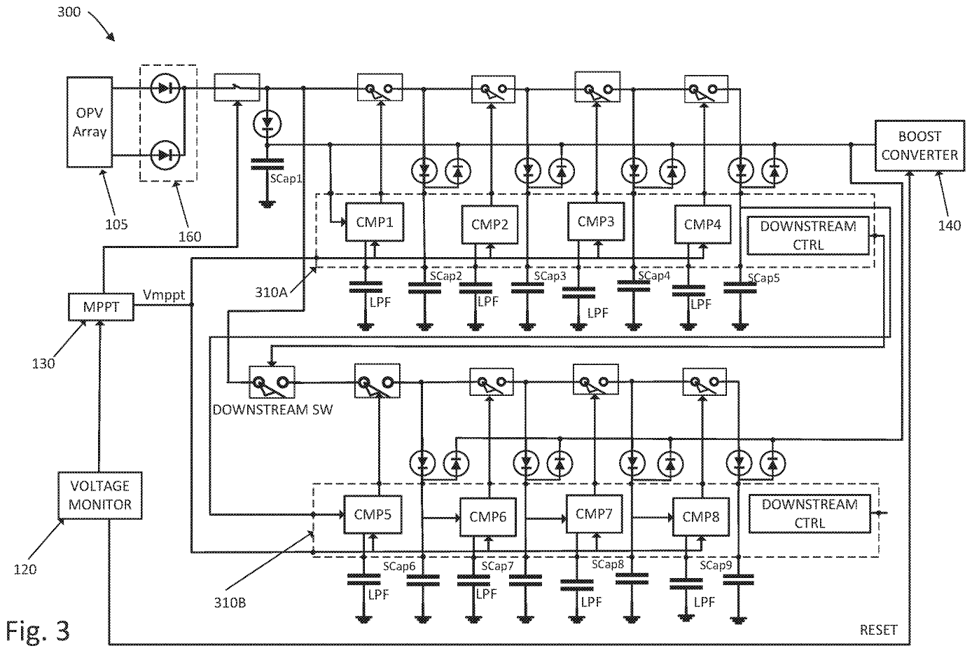

Additional embodiments of the scalable batteryless power supply set forth above, are contemplated wherein elements are implemented as a power management integrated circuit (PMIC). As shown in FIG. 3, two such four-channel/branch devices can be used to create a batteryless power supply 300 with nine energy storage stages wherein CMP1, CMP2, CMP3 and CMP4 are implemented as an integrated circuit (IC) 310A, and CMP5, CMP6, CMP7 and CMP8 are implemented as an integrated circuit (IC) 310B, and wherein the output of the last supercapacitor branch can be made available via a downstream control circuit for further storage branches. The advantage of such a circuit is that the charging current for SCap9 transits via only five switches instead of nine.

According to additional embodiments, further integration can be provided by a batteryless power supply wherein the Schottky diodes are included within the integrated circuits 310A and 310B, and wherein the MOSFET switches SW are incorporated in integrated circuits along with the comparators CMP and Schottky diodes.

The present invention has been described above with reference to a number of exemplary embodiments and examples. It should be appreciated that the particular embodiments shown and described herein are illustrative of the invention and its best mode and are not intended to limit in any way the scope of the invention as set forth in the claims. The features of the various embodiments may stand alone or be combined in any combination. Further, unless otherwise noted, various illustrated steps of a method can be performed sequentially or at the same time, and not necessarily be performed in the order illustrated. It will be recognized that changes and modifications may be made to the exemplary embodiments without departing from the scope of the present invention. These and other changes or modifications are intended to be included within the scope of the present invention, as expressed in the following claims.

1. A scalable batteryless power supply for connection between an energy harvester and a load, comprising:
a maximum power point tracking circuit and input switch for periodically sampling an output voltage of the energy harvester and in response generating a threshold voltage;
a plurality of cascaded energy storage branches separated by additional switches, for cascaded storage of energy from the energy harvester and for powering the load; and
wherein successive ones of the cascaded energy storage branches are activated by the additional switches in sequence from a lowest capacitance to successively higher capacitances based on the threshold voltage.

2. The scalable batteryless power supply of claim 1, wherein each of the plurality of cascaded energy storage branches comprises a supercapacitor, a comparator for comparing voltage across the supercapacitor to the threshold voltage and selectively enabling a respective one of the additional switches, and at least one diode for preventing current from flowing either to an output of the input switch or to an adjacent one of the plurality of cascaded energy storage branches.

3. The scalable batteryless power supply of claim 2, further comprising a boost converter connected to outputs of the plurality of cascaded energy storage branches for drawing current from the supercapacitor for supplying the load and an output switch connected to the boost converter for delivery power to the load.

4. The scalable batteryless power supply of claim 3, further comprising a voltage monitor for generating a voltage reference applied to the maximum power point tracking circuit and a reset signal for controlling operation of the boost converter and output switch.

5. The scalable batteryless power supply of claim 2, wherein the comparator has a first input for sensing the voltage across the supercapacitor via a high impedance resistive divider and a second input for receiving the threshold voltage.

6. The scalable batteryless power supply of claim 5, further including a low pass filter capacitor for preventing the comparator from toggling rapidly due to rapid fluctuations of the voltage across the supercapacitor.

7. The scalable batteryless power supply of claim 6, wherein the low pass filter capacitor has a capacitance in the range of 1 μF to 4.7 μF to minimize toggling of the comparator.

8. The scalable batteryless power supply of claim 1, wherein said lowest capacitance is in the range of 10 mF to 47 mF.

9. The scalable batteryless power supply of claim 8, wherein said lowest capacitance is approximately 22 mF.

10. The scalable batteryless power supply of claim 3, wherein the input switch, output switch and additional switches are P-channel MOSFET switches.

11. The scalable batteryless power supply of claim 2, further including a Zener diode between the input switch and at least one diode to clip the output voltage in the event of spurious voltage spikes from the energy harvester.

12. A method of operating the scalable batteryless power supply of claim 5, comprising:
charging the lowest capacitance one of the cascaded energy storage branches causing the stored voltage to rise and provided the stored voltage remains below the reference voltage, the voltage monitor disables the maximum power point tracking circuit and the boost converter such that all harvested energy goes into said lowest capacitance one of the cascaded energy storage branches, and in the event the stored voltage exceeds the reference voltage the voltage monitor enables the boost converter and maximum power point tracking circuit and opens the output switch to prevent inrush current;
sampling the output voltage of the energy harvester by turning off the input switch;
enabling the boost converter and output switch for powering the load and continued charging of the lowest capacitance one of the cascaded energy storage branches other than when the input switch is opened in order to sample the output voltage of the energy harvester; and
in the event the stored voltage exceeds the threshold voltage charging a next lowest capacitance one of the cascaded energy storage branches.

13. A scalable batteryless power supply for harvesting light energy and powering a load, comprising:
a light energy harvester;
a circuit for periodically sampling an output voltage of the energy harvester and in response generating a reference voltage; and
a plurality of cascaded energy storage branches for storing energy from the energy harvester and powering the load, wherein each energy storage branch triggers charging of a downstream energy storage branch provided the voltage thereacross remains above the reference voltage.

14. The scalable batteryless power supply of claim 13, wherein each of the plurality of cascaded energy storage branches comprises a supercapacitor, a comparator for comparing voltage across the supercapacitor to the reference voltage and selectively triggering the downstream energy storage branch.

15. The scalable batteryless power supply of claim 14, wherein the light energy harvester comprises an organic photovoltaic array.

16. The scalable batteryless power supply of claim 15, wherein the organic photovoltaic array comprises multiple printed organic solar cells connected in series and in parallel.

17. The scalable batteryless power supply of claim 2, wherein the plurality of cascaded energy storage branches comprises two multi-channel branches of supercapacitors, switches, diodes and comparators, and wherein the comparators are implemented in two respective integrated circuits.

18. The scalable batteryless power supply of claim 2, wherein the plurality of cascaded energy storage branches comprises two multi-channel branches of supercapacitors, switches, diodes and comparators, and wherein the comparators and diodes are implemented in two respective integrated circuits.

19. The scalable batteryless power supply of claim 2, wherein the plurality of cascaded energy storage branches comprises two multi-channel branches of supercapacitors, switches, diodes and comparators, and wherein the switches, diodes and comparators are implemented in two respective integrated circuits.
